(19) United States
(12) Patent Application Publication
(10) Pub. No.: US 2015/0329971 A1
(43) Pub. Date: Nov. 19, 2015

(54) METHOD OF IMPROVING ADHESION BETWEEN POLYMER FILM AND METAL LAYER

(71) Applicant: KOREA INSTITUTE OF INDUSTERIAL TECHNOLOGY, Cheonan-si Chungcheongnam-do (KR)

(72) Inventors: Hong-Kee LEE, Incheon (KR); Ho-Nyun LEE, Incheon (KR); Jin-Young HUR, Seoul (KR); Jang-Hun LEE, Seoul (KR); Yoon-Sung HAN, Seoul (KR)

(21) Appl. No.: 14/652,127

(22) PCT Filed: Nov. 1, 2013
(86) PCT No.: PCT/KR2013/009825

§ 371 Date: Jun. 15, 2015

(30) Foreign Application Priority Data
Dec. 13, 2012 (KR) 10-2012-0145504

(51) Int. Cl. C23C 18/16; C23C 14/22; C23C 28/02; C25D 3/38; C25D 5/54; C25D 5/34

(52) U.S. Cl. CPC C23C 18/165; C25D 5/54; C25D 5/34; C23C 28/023; C25D 3/38; C23C 14/22; C23C 18/1689

(57) ABSTRACT

Provided is a method of improving adhesion between a polymer substrate and a metal layer formed on the substrate. The method according to present invention includes (a) performing a surface modification treatment on a polymer film, (b) forming a metal layer on the surface modification treated polymer film, and (c) performing at least one selected from an aging treatment or a current application treatment on the metal layer.

### TECHNICAL FIELD

The present invention relates to method of improving adhesion between a polymer film and a metal layer formed on the film, and more particularly, to a method capable of obtaining adhesion which is improved in comparison to the conventional method by forming a metal layer on a polymer film and then performing an aging treatment, current application, or an aging treatment in a specific atmosphere alone or in combination.

### BACKGROUND ART

Currently, as a technique of forming a metal circuit pattern on a polymer film material that is used as a flexible printed circuit board and dielectrics for packages, a method of preparing a metal circuit pattern has been generally and widely used, in which a circuit pattern having a predetermined shape is formed on the surface of a polymer, on which a thin copper foil is stacked or deposited, using a photoresist process and copper is then etched.

As a method of forming a metal layer on a polymer material, a method of performing a surface modification treatment on a polymer film using plasma ions to improve adhesion and then forming a conductive metal adhesion layer on the surface of the film by using a dry surface treatment technique such as sputtering or metal deposition, a method of forming a metal coating layer using an electroplating technique depending on product conditions, and a laminate method in which a copper film is directly bonded to the surface of a polymer film, or a casting method has been used.

However, these methods have limitations in that the formation of a uniform metal layer is not facilitated or high process costs are required.

In order to address these limitations, research and development into a metallization treatment of a polymer film through wet processing have been actively conducted. However, since physical properties, for example, low adhesion between the metal layer and the polymer film, do not meet the requirements of the market, a commercial application has not been achieved.

However, since the wet processing may have advantages, for example, simple process and equipment, low cost, high productivity, and the formation of a uniform metal coating layer, the wet processing is a process with great potential if the requirements of the market, for example, the improvement of the adhesion between the metal and the polymer, are resolved.

### DISCLOSURE OF THE INVENTION

### Technical Problem

The purpose of the present invention is to provide a method of significantly improving adhesion between a polymer film and a metal layer formed on the film by a simple process when forming the metal layer on the polymer film through wet processing.

The purpose of the present invention is also to provide a polymer film in which the adhesion to the metal layer is improved by the above method.

### Technical Solution

According to a first aspect of the present invention, there is provided a method of forming a metal layer on a polymer film including: (a) performing a surface modification treatment on a polymer film; (b) forming a metal layer on the surface modification treated polymer film; and (c) performing at least one selected from an aging treatment or a current application treatment on the metal layer.

According to a second aspect of the present invention, there is provided a method of forming a metal layer on a polymer film including: (a) performing a surface modification treatment on a polymer film; (b) forming a metal seed layer on the surface modification treated polymer film; (c) performing at least one selected from an aging treatment or a current application treatment on the metal seed layer; and (d) forming a metal layer on the metal seed layer.

According to the first or second aspect of the present invention, the polymer film may be a single layer film or a multilayer film formed of at least one selected from a thermosetting resin, a thermoplastic resin, a polyester resin, a polyimide resin, a condensation polymer, or a mixture of two or more thereof.

According to the first or second aspect of the present invention, the metal layer may be formed of at least one selected from copper (Cu), nickel (Ni), cobalt (Co), titanium (Ti), aluminum (Al), chromium (Cr), molybdenum (Mo), or an alloy thereof.

According to the first or second aspect of the present invention, a tiecoat layer may be formed on the polymer film before the forming of the metal layer or the metal seed layer.

According to the first or second aspect of the present invention, the aging treatment may be performed for 12 hours or more, preferably 24 hours or more, and more preferably 48 hours or more.

According to the first or second aspect of the present invention, the aging treatment may be performed in an atmosphere having a relative humidity of 10% or more, preferably 50% or more, and more preferably 80% or more in a temperature range of 0° C. to 100° C.

According to the first or second aspect of the present invention, the current application treatment may be performed by applying a current density of 0.005 mA/cm² to 1 A/cm² to a surface of the metal layer.

According to the first or second aspect of the present invention, the metal layer may be formed by a method selected from a plating method or a physical vapor deposition (PVD) method.

According to the second aspect of the present invention, the metal seed layer may be formed by a method selected from an electroless plating method, an electroless plating and electroplating method, and a PVD method.

According to the first or second aspect of the present invention, the surface modification treatment may include at least one selected from immersion in an acid or alkaline solution, an ultraviolet (UV) treatment, or a plasma treatment.

### Advantageous Effects

When performing an aging treatment, a current application treatment, and an aging treatment in a specific atmosphere on a metal seed layer or a metal layer alone or in combination according to the present invention, the adhesion of the metal layer formed on a polymer film is considerably improved.

Also, since a method of improving adhesion according to the present invention is performed by a simple process, such as the aging treatment, short-time current application, or an aging treatment in a specific atmosphere, on a metal seed layer and/or a metal layer, the adhesion may be improved at a low cost.

Furthermore, the method of improving adhesion according to the present invention is not limited to wet processing, but may also be used in dry processing.

### BRIEF DESCRIPTION OF THE DRAWINGS

FIG. 1 illustrates the result of measuring changes in adhesion according to an aging treatment;

FIG. 2 illustrates the result of measuring changes in adhesion according to a current application treatment;

FIG. 3 illustrates the result of measuring changes in adhesion according to an aging treatment in an atmosphere; and

FIG. 4 illustrates the result of measuring changes in adhesion due to being left standing after the aging treatment in an atmosphere.

### MODE FOR CARRYING OUT THE INVENTION

Hereinafter, the present invention will be described in more detail, according to specific examples. However, the following examples are merely provided to more clearly understand the present invention, not to limit the scope of the present invention.

The present inventors conducted research to improve adhesion between a polymer film and a metal layer when forming the metal layer on the polymer film, in particular, when forming the metal layer through wet processing that is capable of forming the metal layer at a low cost.

As a result, the present inventors recognized that the adhesion between the polymer and the metal layer is significantly improved if the metal layer (metal seed layer) is formed on the polymer film and a predetermined treatment, for example, an aging treatment (particularly, aging in a water environment or underwater environment) or current application treatment, is then performed on the metal layer.

A method of improving the adhesion between the polymer and the metal layer according to present invention includes: (a) performing a surface modification treatment on a polymer film; (b) forming a metal layer on the surface modification treated polymer film; and (c) performing at least one selected from an aging treatment or a current application treatment on the metal layer.

In this case, in the forming of the metal layer, in a case in which the metal layer is formed after forming a metal seed layer, for example, in a case in which the seed layer is formed on a polymer film through electroless plating and the metal layer is then formed through electroplating, at least one selected from an aging treatment or a current application treatment is performed on the metal seed layer, and the metal layer may then be formed.

Also, before the forming of the metal layer or the metal seed layer, a tiecoat layer may be formed on the polymer film.

The polymer film may be a single layer or a multilayer film formed of at least one selected from a thermosetting resin, a thermoplastic resin, a polyester resin, a polyimide resin, a condensation polymer, or a mixture of two or more thereof.

Also, a phenol resin, a phenolaldehyde resin, a furan resin, an aminoplast resin, an alkyd resin, an allyl resin, an epoxy resin, an epoxy prepreg, a polyurethane resin, a thermosetting polyester resin, or a silicon resin may be used as the thermosetting resin.

Furthermore, polyethylene, polypropylene, an ethylene/vinyl copolymer, or an ethylene acrylic acid copolymer may be used as the thermoplastic resin.

Also, ones prepared from divalent aliphatic and aromatic carboxylic acids and diol or triol may be used as the polyester resin.

Polyamide, polyetherimide, polysulfone, polyethersulfone, polybenzazole, and aromatic polysulfone may be used as the condensation polymer.

As the metal layer and the metal seed layer, a material, such as copper (Cu), nickel (Ni), or an alloy thereof, may be used, but the present invention is not limited thereto.

Also, with respect to the metal seed layer, since the metal layer to be formed on the metal seed layer may be difficult to be formed to a uniform thickness when a thickness of the metal seed layer is excessively small, the metal seed layer may be formed to a thickness of at least 100 nm or more.

The tiecoat layer may be formed of Ni, chromium (Cr), molybdenum (Mo), cobalt (Co), or an alloy thereof.

The tiecoat layer may be formed to a thickness of 1 nm to 40 nm.

The reason for this is that when the thickness is less than 1 nm, an improvement in the adhesion may not be sufficient, and when the thickness is greater than 40 nm, a subsequent etching process may not be facilitated.

Various surface treatments, such as immersion in an acid or alkaline solution according to the type of polymer, an ultraviolet (UV) treatment, or a plasma treatment, may be performed as the surface modification treatment.

The surface modification treatment may include performing catalyst and activation processes after performing a primary surface treatment.

In the forming of the metal layer or the metal seed layer on the surface modification treated polymer film, a known film formation method, such as a method of performing electroplating after electroless plating, sputtering, vacuum deposition, and ion plating, may be used.

The aging treatment on the metal layer or the metal seed layer denotes a treatment in which the metal layer or the metal seed layer is formed and is then left standing for at least 12 hours, preferably 24 hours, and most preferably 48 hours without performing a subsequent process on the metal layer or the metal seed layer.

In this case, an air atmosphere is possible for the atmosphere of the aging treatment. However, the aging treatment, for example, may be performed in parallel with a so-called “atmosphere treatment” which is carried out in a water-rich state instead of a normal air atmosphere.

During the atmosphere treatment, relative humidity in a temperature range of 0° C. to 100° C. must be at least 10% or more, may be 50% or more, and for example, may be 80% or more.

The current application treatment on the metal layer or the metal seed layer is a process in which a current density of 0.05 mA/cm² to 1 A/cm² is instantaneously applied to the surface of the metal layer or the metal seed layer, in particular, to the metal seed layer in a case in which the metal seed layer is formed by electroless plating as wet processing and the metal layer is then formed on the metal seed layer by electroplating, for 0.1 second to 1 hour.

The adhesion between the metal layer and the polymer may be significantly increased through the above process.

The current application treatment may be performed for a minimum of 0.1 second or more, and since the above effect may be saturated even if the treatment is performed for 1 hour or more, it is not desirable to perform the current application treatment for 1 hour or more.

The current application treatment may be a more favorable method than the aging treatment in terms of the fact that improved adhesion may be obtained by a short-time treatment in comparison to the aging treatment.

### Example 1

In forming a copper plating layer on a polymer film through electroless plating and electroplating, Example 1 of the present invention corresponds to performing an aging treatment in which a predetermined time was maintained in the atmosphere after the formation of an electroless plating layer or the formation of an electroplating layer.

Specifically, a 25 μm thick polyimide Kapton film from DuPont in the U.S. was used as the polymer film.

First, a pretreatment of the polyimide film was performed in the sequence of a surface modification treatment, a washing treatment, a neutralization treatment, a washing treatment, a catalyst treatment, a washing treatment, and an activation treatment.

The surface modification treatment was performed by a method of dipping the polyimide film in a mixed solution of 1 M KOH and 0.9 M ethylene diamine (EDA) at 50° C. for 5 minutes, and the neutralization treatment was performed by a method of dipping the polyimide film in a 0.2 M HCl solution for 5 minutes. Also, the catalyst and activation processes were respectively performed for 4 minutes and 2 minutes using SnCl₂ and PdCl₂ at room temperature.

The polyimide film subjected to the pretreatment was plated at a pH of 12.5 for 10 minutes using an electroless copper plating solution in which formaldehyde (20 mL/L) as a reducing agent, Rochelle salt (50 g/L) as a complexing agent, and sodium hydroxide as a pH adjuster were added to a copper sulfate solution (10 g/L). A thickness of the electroless copper plated layer thus formed was about 100 nm.

Subsequently, copper electroplating was performed on the electroless copper plated layer to form a plated layer having a thickness of about 10 μm.

Samples subjected to the electroless copper plating were immediately electroplated, and the samples having an electro-copper plated layer formed thereon were then left standing in the air for 0 hour, 12 hours, 24 hours, and 48 hours, respectively. Then, adhesions of the electro-cooper plated layers were evaluated.

Also, the electroless copper plated layers were respectively maintained in the atmosphere for 0 hour, 12 hours, 24 hours, and 48 hours and electro-copper plated layers were immediately formed. Then, adhesions of the electro-copper plated layers were also evaluated.

That is, a case, in which the electroless copper plating and the electro-copper plating were continuously performed and the aging treatment was then performed, and a case, in which the electroless plating (i.e., seed layer) was performed, the intermediate aging treatment was then performed, and the electro-copper plating was performed, were evaluated whether there was any difference between the adhesions between the polyimide film and the copper plating layer.

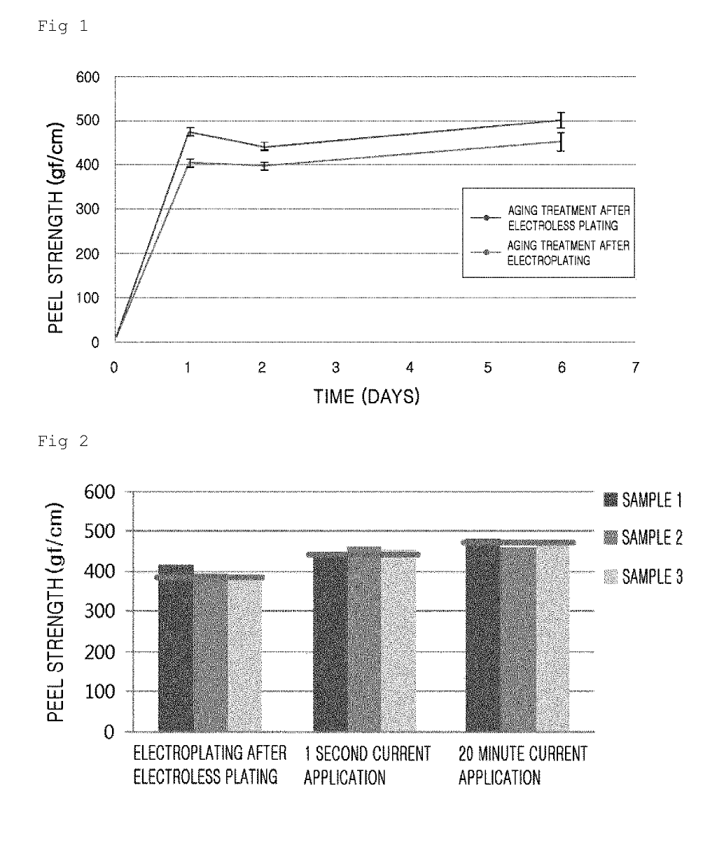

Measurements of the adhesion between the polyimide film and the copper plating layer were performed by a T-peel test (180° peel) using an Instron 3344 (Universal Testing Machine) at a cross head speed of 50.8 mm/min, and the results thereof are presented in FIG. 1.

As illustrated in FIG. 1, the samples, in which the electroless copper plating and the electro-copper plating were continuously performed and the aging treatment was then performed, and the case, in which the aging treatment was performed after performing the electroless plating and the electroplating was then performed, exhibited the same tendency that, when the aging treatment was performed, the adhesion was rapidly increased to 24 hours and then saturated.

However, it may be understood that the case, in which the electroplated layer was formed after performing the aging treatment on the electroless plated layer (seed layer), had about 20% or more higher adhesion than the case in which the electroless plating and the electroplating were continuously performed.

That is, the aging treatment on the seed layer was advantageous in increasing the adhesion between the polymer film and the metal layer in comparison to the case in which the aging treatment was performed after the completion of the metal layer.

### Example 2

In forming a copper plating layer on a polymer film through electroless plating and electroplating, Example 2 of the present invention corresponds to performing a current application treatment in which a predetermined current was applied to an electroless plated layer and/or an electroplated layer.

The electroless plating and the electroplating were continuously performed under the same electroless copper plating and electro-copper plating conditions as Example 1. Then, three samples for each case, i.e., the case, in which an aging treatment in the air was performed for 2 days and a current application treatment was then performed under two conditions, and the case, in which the 2-day aging treatment was only performed for comparing the effect of the current application treatment, were prepared.

The current application treatment was performed in two ways, i.e., a case in which a current of 1 mA was applied for 1 second after performing the 2-day aging treatment, and a case in which a current of 1 mA was applied for 20 minutes after performing the 2-day aging treatment. In this case, an area of each plating layer formed on the samples was 60 cm².

The adhesions of the samples thus prepared were measured, and the results thereof are presented in FIG. 2.

As illustrated in FIG. 2, the case, in which the 2-day aging treatment was only performed without performing the current application treatment, exhibited a peel strength of about 397 gf/cm, and the two cases of applying a current exhibited a peel strength of 454 gf/cm and 471 gf/cm, respectively.

The above results indicated that the current application treatment on the metal layer was effective in improving the adhesion between the polymer film and the metal layer.

In particular, since the current application treatment may be performed in a short period of time and may also be performed with almost no processing cost, the current application treatment may be used as the most efficient method of improving the adhesion of the metal layer.

### Example 3

In forming a copper plating layer on a polymer film through electroless plating and electroplating, Example 3 of the present invention corresponds to adjusting an atmosphere in which an aging treatment was performed, when performing the aging treatment after the formation of an electroless plating layer or the formation of an electroplating layer.

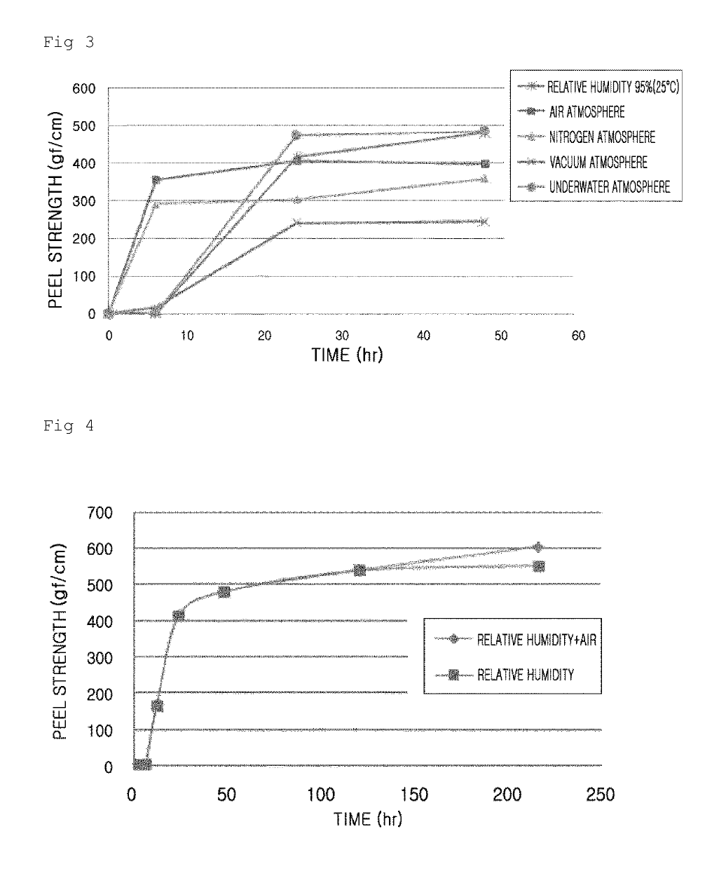

The electroless copper plating and the electro-copper plating were continuously performed under the same electroless copper plating and electro-copper plating conditions as Example 1. Then, adhesion depending on time was measured after samples were respectively left standing in an atmosphere having a relative humidity of 95% at 25° C., a nitrogen gas atmosphere, a vacuum atmosphere, and an underwater atmosphere, and the results thereof are presented in FIG. 3.

In a case in which the aging treatments were respectively performed in the above atmospheres for 1 day or more, the case of performing the aging treatment in the underwater atmosphere and the case of performing the aging treatment in the atmosphere having a relative humidity of 95% at 25° C. exhibited the highest peel strength.

The adhesion was decreased in the sequence of the air atmosphere, the nitrogen atmosphere, and the vacuum atmosphere.

From the above results, it may be understood that, for the improvement of the adhesion between the polyimide film and the copper plating layer, it is advantageous to perform the aging treatment in the underwater atmosphere or water-rich atmosphere having a high humidity in comparison to the air atmosphere.

Also, referring to FIG. 3, a difference between the adhesions between the polyimide film and the copper layer reached about 2 times depending on the atmosphere in which the aging treatment was performed, and it may be understood that the aging treatment in the atmosphere for at least 1 day was required to sufficiently improve the adhesion.

Also, in FIG. 4, in order to confirm whether the increased peel strength returned to that in the state of being left standing in the air in a case in which the aging treatment was performed in the atmosphere having a relative humidity of 95% at 25° C. and the sample was then left standing in the air, adhesion of a sample, which was left standing for 5 days in the atmosphere having a relative humidity of 95% at 25° C. and was left standing for 4 days in the air, and adhesion of a sample, which was left standing for 9 days in the atmosphere having a relative humidity of 95% at 25° C., were compared.

As illustrated in FIG. 4, the case, in which the sample was left standing for 4 days after changing the atmosphere into the air, exhibited relatively high peel strength.

In consideration of the fact that a peel strength of the sample left standing for 6 days in the air under the same condition was about 450 gf/cm, it may be understood that the adhesion increased by the aging treatment in the atmosphere was maintained as it is even if the atmosphere was changed.

1. A method of improving adhesion between a polymer film and a metal layer, the method comprising:
(a) performing a surface modification treatment on a polymer film;
(b) forming a metal layer on the surface modification treated polymer film; and
(c) performing at least one selected from an aging treatment or a current application treatment on the metal layer.

2. A method of improving adhesion between a polymer film and a metal layer, the method comprising:
(a) performing a surface modification treatment on a polymer film;
(b) forming a metal seed layer on the surface modification treated polymer film;
(c) performing at least one selected from an aging treatment or a current application treatment on the metal seed layer; and
(d) forming a metal layer on the metal seed layer.

3. The method of claim 1, wherein the polymer film is a single layer film or a multilayer film formed of at least one selected from a thermosetting resin, a thermoplastic resin, a polyester resin, a polyimide resin, a condensation polymer, or a mixture of two or more thereof.

4. The method of claim 1, wherein the metal layer is formed of copper (Cu), nickel (Ni), cobalt (Co), titanium (Ti), aluminum (Al), chromium (Cr), molybdenum (Mo), or an alloy thereof.

5. The method of claim 1, wherein a tiecoat layer is formed on the polymer film before the forming of the metal layer or the metal seed layer.

6. The method of claim 1, wherein the aging treatment is performed for 12 hours or more.

7. The method of claim 6, wherein the aging treatment is performed in an atmosphere having a relative humidity of 10% or more in a temperature range of 0° C. to 100° C.

8. The method of claim 1, wherein the current application treatment is performed by applying a current density of 0.1 mA/cm2 to 1 A/cm2 to a surface of the metal layer.

9. The method of claim 1, wherein the metal layer is formed by a method selected from a plating method or a physical vapor deposition (PVD) method.

10. The method of claim 2, wherein the metal seed layer is formed by a method selected from electroless plating, electroless plating and electroplating, or a PVD method.

11. The method of claim 1, wherein the surface modification treatment comprises at least one selected from immersion in an acid or alkaline solution, an ultraviolet (UV) treatment, or a plasma treatment.

12. The method of claim 2, wherein the polymer film is a single layer film or a multilayer film formed of at least one selected from a thermosetting resin, a thermoplastic resin, a polyester resin, a polyimide resin, a condensation polymer, or a mixture of two or more thereof.

13. The method of claim 2, wherein the metal layer is formed of copper (Cu), nickel (Ni), cobalt (Co), titanium (Ti), aluminum (Al), chromium (Cr), molybdenum (Mo), or an alloy thereof.

14. The method of claim 2, wherein a tiecoat layer is formed on the polymer film before the forming of the metal layer or the metal seed layer.

15. The method of claim 2, wherein the aging treatment is performed for 12 hours or more.

16. The method of claim 2, wherein the current application treatment is performed by applying a current density of 0.1 mA/cm2 to 1 A/cm2 to a surface of the metal layer.

17. The method of claim 2, wherein the metal layer is formed by a method selected from a plating method or a physical vapor deposition (PVD) method.

18. The method of claim 2, wherein the surface modification treatment comprises at least one selected from immersion in an acid or alkaline solution, an ultraviolet (UV) treatment, or a plasma treatment.
